(19) United States
(12) Patent Application Publication
(10) Pub. No.: US 2007/0001253 A1
(43) Pub. Date: Jan. 4, 2007

(54) Using extended gate field effect transistor to design and analyze the chinese medicine biosensor

(75) Inventors: Shen-Kan Hsiung, Chung-Li (TW); Jung-Chuan Chou, Douliou City (TW); Tai-Ping Sun, Jhongli City (TW); Chia-Yu Yen, Cingshuei Township (TW)

Correspondence Address: TROXELL LAW OFFICE PLLC;ONE SKYLINE PLACE, SUITE 1404, 5205 LEESBURG PIKE, FALLS CHURCH, VA, 22041, US

(73) Assignee: Chung Yuan Christian University

(21) Appl. No.: 11/284,810

(22) Filed: Nov. 23, 2005

(30) Foreign Application Priority Data
Jul. 1, 2005 (TW) 094100460

(51) Int. Cl. H01L 31/0203

(52) U.S. Cl. 257/434; 204/192.15; 205/775

(57) ABSTRACT

In this invention, an extended gate FET with a tin dioxide membrane is applied to fabricate a berberine sensor. There are two methods for fabricating the berberine sensor. First, it is mixed by the macromolecule polymer and electrocatalytic activities. The membrane is adsorbed on the SnO₂/ITO glass and the berberine sensor is completed. Second, a polymer is used to immobilize enzyme on the substrate and detect the berberine. In this invention, the extended gate field effect transistor of the SnO₂/ITO glass is applied to fabricate a durable berberine detection electrode. One of the berberine sensors that is macromolecule polymer, the optimal measurement environment is in distilled water and the best response curve can be realized, the detection rang is from 1×10⁻³M to 5×10⁻⁷M and the linear range is about 121.47 mV/pC. The berberine sensor based on the enzyme that optimal measurement environment is in 0.1M phosphate buffer solution at pH7.4 and better response curves can be obtained. Although the detection rang is from 1×10⁻³M to 1×10⁻⁷M, the linear range is not better which is about 20.05 mV/pC.

### BACKGROUND OF THE INVENTION

1. Field of the Invention

The present invention uses tin dioxide as a base of an extended gate field effect transistor with a separating architecture, which can use tin dioxide (SnO2)/indium tin oxide (ITO) glass as a separating architecture to form a berberine detection electrode on berberine membrane. The scope of applicability of this architecture covers the range of Chinese chemical detectors capable of detecting the berberine content in Chinese herbal medicines. A mass duplication of elements and a low cost are taken in consideration for the research and development, and thus an extended architecture is used to meet these requirements, and the development of this chemical sensor can be integrated with the industry quickly to timely introduce the product to market.

2. Description of the Related Art

Chemical molecules of many medicines will release ions, and an ion-sensitive electrode is a specific ion detector device having minimized and measurable-by-meters features, and being applicable for automatic system design. With the introduction of the ion sensitive field effect transistor, other applications are developed extensively, such as the detection of pH values, potassium, sodium, calcium, chlorine ion, fluorine ion and iodine ion in blood or any liquid environment [Pavel Neuzil, “ISFET integrated sensor technology”, Sensors and Actuators B, Vol. 24-25, 1995, pp. 232-235; Wang Zheng-Xiao, “Applications of penicillinase FET in penicillin-fermentation engineering”, Sensors and Actuators B, Vol. 13-14, 1993, pp. 568-569; A. Haemmeril, J. Janata, H. Mack Brown, “Electrical characteristics of K+ and Cl− EFT microelectrodes”, Sensors and Actuators B, Vol. 3, 1982-1983, pp. 149-158; B. H. Van Der Schoot, H. H. Van Den Vlekkert, N. F. De Rooij, A. Van Den Berg and A. Grisel, “A flow injection analysis system with glass-bonded ISFETs for the simultaneous detection of calcium and potassium ion and pH”, Sensors and Actuators B, Vol. 4, 1991, pp. 145-149; D. Wilhelm, H. Voigt, W. Treichel, R. Ferretti and S. Prasad, “pH sensor based on differential measurements on one pH-FET chip”, Sensors and Actuators B, Vol. 4, 1991, pp. 145-149; W. Moritz, F. Lisdat, B. H. Van Der Schoot, N. F. De Rooij, H. H. Van Den H. C. G. Ligtenberg, I. Grohmann, “Flow injection analysis using pH/pF ISFET combinations for determination of very low fluoride concentrations”, Sensors and Actuators B, Vol. 15-16, 1993, pp. 223-227] mainly base on ISFET as the basic principle. The ion-specific electrode does not focus at all ions, but it is a chemical sensor for detecting a specific ion only. The term “ion-selective” refers to a specific ion detected in a solution, but the interference by other ions also has an effect to a certain extent, and the effect is not significant. Therefore, the detection on a specific ion will not have a too-large error.

The electrochemical analysis technology adopts a method of using the electrochemical properties of a matter to detect an electric potential, current, or capacity of a chemical battery for carrying out the analysis. This method is also known as an electrochemical analysis method. There are several electrochemical analysis methods such as an analysis using the electromotive force of an original battery to calculate the content of a matter, and this method is called “Potential Method” or “Potential Analysis Method”. The potential analysis method is an analysis method that uses the relation between the electric potential of an electrode and the concentration to calculate the content of a matter. The basic formula for the electric potential of an electrode is known as “Nernst Formula”.

Using an ion-sensitive electrode analysis method to detect chemicals is called an electric potential analysis method, and its related researches and analyses become increasingly valuable, and its sensitivity of detecting the ions released by certain chemicals can reach up to the level of 10⁻⁶˜10⁻⁷ [S. Caras, J. Janata, “Field effect transistor sensitive to penicillin”, Analytical Chemistry 52, 1980, pp. 1935-1937; Y. Su, M. Tomassetti, M. P. Sammartion, G. Crescentini, L. Campanella, “A new salicylate ISFET for the determination of salicylic and acetylsalicylic acid in drug”, Journal of Pharmaceutical and Biomedical Analysis 13, 1995, pp. 449-457; L. Campanella, L. Aiello, C. Colapicchioni, M. Tomassetti, “Lidocaine and benzalkonium analysis and titration in drugs using new ISFET devices”, Journal of Pharmaceutical and Biomedical Analysis 18, 1998, pp. 117-125; Masayuki Hara, “Application of P450s for biosensing: combination of biotechnology and electrochemistry”, Materials Science and Engineering C 12 , 2000, pp. 103-109; Sven Ingebrandt, Chi-Kong Yeung, Michael Krause, Andreas Offenhausser, “Cardiomyocyte-transistor-hybrids for sensor application”, Biosensors and Bioelectronics 16, 2001, pp. 565-570]. The types of ion selectivity of an electrode is based on the ion-sensitive electrode, and most of them are membrane electrodes, and the membrane is made from glass materials according to the electric potential response mechanism of the membrane, and the composition and structure of the membrane. Since the compositions of glass are different, therefore an ion-selective electrode for H+, Na+, K+, Li+ and Ag+, etc can be made. One of the properties of the selectivity electrode has selectivity for a specific ion. It is even better to achieve the specificity, and selects an ion-selective membrane made of a macromolecule substance and an ion-selective substance to accomplish this function.

Related patents are listed below:

(1) Stephen N. Cozzette, Graham Davis, Imants R. Lauks, Randall M. Mier, Sylvia Piznik, Nicolaas Smit, Paul Van Der Werf, Henry J. Wieck, System and method of microdispensing and arrays of biolayers provided by same”, U.S. patent, Patent Number: 20020090738, Date of patent: Jul. 11, 2002

This patent has disclosed an efficient method for a microfabrication of electronic devices adopted for the analysis of biologically significant analyte species. The techniques of the present invention allow users to closely control over the dimensional features of the various components and layers established on a suitable substrate. Such control extends to those parts of the devices which incorporate the biological components which enable these devices to function as biological sensors. The materials and methods disclosed herein thus provide an effective means for the mass production of uniform wholly microfabricated biosensors. Various embodiments of the devices themselves are described herein which are especially suited for real time analyses of biological samples in a clinical setting. In particular, the present invention describes assays which can be performed using certain ligand/ligand receptor-based biosensor embodiments. The present invention also discloses a method for the electrochemical detection of particular analyte species of biological and physiological significance.

(2) Jung-Chuan Chou, Wen-Yaw Chung, Shen-Kan Hsiung, Tai-Ping Sun, Hung-Kwei Liao, “Fabrication of a multi-structure ion sensitive field effect transistor with a pH sensing layer of a tin oxide thin film”, U.S. patent, U.S. Pat. No. 6,218,208, Date of patent: Apr. 17, 2001.

This patent has disclosed that a sensitive material-tin oxide (SnO₂) obtained by thermal evaporation or by RF reactive sputtering is used as a high-pH-sensitive material for a Multi-Structure Ion Sensitive Field Effect Transistor. The multi-structure of this Ion Sensitive Field Effect Transistor (ISFET) includes SnO₂/SiO₂ gate ISFET or SnO₂/Si₃ N₄/SiO₂ gate ISFET respectively, and which have high performances such as a linear pH sensitivity of approximately 56˜58 mV/pH in a concentration range between pH2 and pH10. A low drift characteristic of approximately 5 mv/day, response time is less than 0.1 second, and an isothermal point of this ISFET sensor can be obtained if the device operates with an adequate drain-source current. In addition, this invention has other advantages, such as the inexpensive fabrication system, low cost, and mass production characteristics. Based on these characteristics, a disposal sensing device can be achieved. Thus, this invention has a high feasibility in Ion Sensitive Field Effect Transistor.

(3) Noboru Oyama, Takeshi Shimomura, Shuichiro Yamaguchi, “Ion-sensitive FET sensor”, U.S. patent, U.S. Pat. No. 4,816,118, Date of patent: Mar. 28, 1989.

This patent has disclosed that an ion-sensitive FET sensor has a MOSFET gate isolating membrane whose surface is covered by an ion-sensitive layer. A redox layer having a redox function is provided between the isolating membrane and the ion-sensitive layer to improve operating stability and speed of response. An electrically conductive layer or a combination of a thin metal film and an electrically conductive layer is provided between the isolating membrane and the redox layer to further improve operating stability, the adhesion of the layers and the durability of the sensor. Also disclosed are optimum materials for use as an ion carrier employed in the ion-sensitive layer. This invention relates to an ion-sensitive FET sensor and, more particularly, to an ion-sensitive FET sensor for measuring the ionic concentration of a solution by the potentiometric response of an electrode. The ion-sensitive FET sensor disclosed herein is especially suited for measurement of ionic concentration within a living body.

(4) Byung Ki Sohn, “Measuring circuit with a biosensor utilizing ion sensitive field effect transistors”, U.S. patent, U.S. Pat. No. 5,309,085, Date of patent: Mar. 3, 1994.

This patent has disclosed that a measuring circuit with a biosensor utilizing ion sensitive field effect transistors having a simplified structure and is advantageous to integration. The measuring circuit comprises two ion sensitive FET input devices composed of an enzyme FET having an enzyme sensitive membrane on the gate and a reference FET, and a differential amplifier for amplifying the outputs of the enzyme FET and the reference FET. The drift phenomena of the ion sensitive FETs due to the use of a non-stable quasi-reference electrode as well as the temperature dependence thereof can be eliminated by the differential amplifier consisting of MOSFETs having the same channel as the ion sensitive FETs. The ion sensitive FET biosensor and the measuring circuit can be integrated into one chip.

(5) Patrick T. Cahalan, Michelle A. Schwinghammer, “Ion selective membranes for use in ion sensing electrodes”, U.S. patent, U.S. Pat. No. 4,565,666, Date of patent: Jan. 21, 1986.

This patent has disclosed a method of producing an ion-selective membrane and an ion-sensitive electrode employing an ion-selective membrane. The method of producing an ion-selective membrane comprises soaking a plastic member of the desired shape in a solution of an ion-selective material dissolved in a volatile solvent which is a swelling agent for the plastic of which the member is fabricated. By this method, a tubular structure including an ion-selective membrane, for example, may more easily be produced. This method has as a major advantage that it allows the use of pre-formed, commercially available plastic products, such as single and bitumen tubing, to easily and simply fabricate a variety of ion-sensing electrodes.

(6) Patrick T. Cahalan, Michelle A. Schwinghammer, “Combination ion selective electrode”, U.S. patent, U.S. Pat. No. 4,486,290, Date of patent: Dec. 4, 1984

This patent has disclosed a combination ion sensing and reference electrode and a method for producing it. The electrode is formed of bitumen plastic tubing using one lumen as sensing chamber and the other as a reference chamber. A portion of the sensing chamber extends distally relative to the reference chamber, and is permeated with an ion selective material by soaking that portion in a solution containing the ion selective material. The method of manufacture is thereby simplified and sealing of the chambers is improved.

This invention relates to electrodes for measuring ion concentrations in aqueous solutions and to methods of manufacturing such electrodes and the ion-selective membranes they employ.

Ion-sensing electrodes selectively responsive to ionic activities in aqueous solutions are well known to the art. The known relationship between ionic activity and ion concentration permits these electrodes to be used to measure ion concentrations. In such electrodes, selective ion exchange occurs through an interface between a selective ion exchange material and the solution to be sampled. Many recent electrode designs have employed ion-selective membranes which retain the ion-selective material in a matrix of organic material such as polyvinylchloride or other plastic.

We provide an extended architecture to produce durable berberine selective electrode. Since the extended architecture has the feature of a low cost, a small volume, an easy packaging, having components easily affected by light, a simple preprocessing of medicine samples, and overcoming the shortcomings of the bulky and expensive traditional equipments, therefore the invention can be used for measuring anytime, and is suitable for developing medical sensor.

### SUMMARY OF THE INVENTION

Therefore, it is a primary object of the present invention to provide an extended field effect transistor that uses tin dioxide as a membrane of the extended gate field effect transistor with a separating architecture to produce a berberine sensor. There are two methods of producing a berberine sensor: one method is to mix macromolecule polymers and electrocatalytic substances deposited on the surface of an extended SnO₂/ITO glass substrate with a separating architecture to produce a complete berberine detection electrode; and the other method is to use macromolecular bonded enzyme to carry out the detection.

Another object of the present invention is to provide an extended SnO₂/ITO glass ion sensitive field effect transistor with a separating architecture to fabricate a durable berberine detection electrode, which is a membrane structure of an electrocatalytic substance covered by macromolecules, and its berberine detection electrode has the optimal response curve in the deionized measuring environment and can detect within a range 1×10−3˜5×10−7 M of the concentration of the berberine, a linear range of 121.47 mV/pC, and the enzyme-based berberine electrode has a better detecting characteristic when detected in a 0.1M phosphate and a pH value of 7.4. The detection range of the concentration of berberine is 1×10−3˜1×10−7 M, but its detection level is less sensitive and is 20.25 mV/pC.

Another object of the present invention is to provide a method of producing an ion-sensitive electrode that uses the ion-sensitive electrode for a detection of berberine in a water soluble solvent.

To achieve the foregoing objects, the extended field effect transistor with a separating architecture comprises: an indium tin oxide (ITO)/glass used for forming a substrate; a tin dioxide (SnO₂) used for forming an oxide layer; and a sealing layer for sealing the substrate and the oxide layer and only leaving a sensing windows that is in contact with a berberine membrane; wherein the oxide layer is sputtered to deposit the tin dioxide onto the indium tin oxide (ITO)/glass substrate to form an extended gate field effect transistor (EGFET) with a separating architecture.

To achieve the foregoing objects, a method of producing an ion-sensitive electrode of the present invention comprises the following steps: cutting an indium tin oxide (ITO) substrate into a desired size and using a supersonic vibrator to rinse the indium tin oxide (ITO) glass substrate by methanol first and then by deionized water for a predetermined time; using a radio frequency sputtering (R. F. Sputtering) method to splutter a tin dioxide (SnO2) membrane onto the indium tin oxide (ITO) glass substrate; using a silver paste to fix a conductive wire onto a reserved portion of the indium tin oxide (ITO) glass substrate, after the membrane is spluttered, and then the substrate is placed into a high-temperature oven for a predetermined time; using a sealing layer to package the components and just leaving a window in contact with the membrane after the conductive wire is fixed, and the substrate is placed into an oven for a predetermined time after the packaging is completed, and completing the production of an extended gate field effect transistor of a separating architecture after the sealing layer is hardened.

To achieve the foregoing objects, a potential detection method using an ion-sensitive electrode comprises the steps of: using a meter amplifier as a read-out circuit; contacting the membrane of the berberine selective electrode with a buffering liquid; and using a voltage-time correction curve as a potential response curve.

### BRIEF DESCRIPTION OF THE DRAWINGS

FIG. 1 is a cross-sectional view of an ion selective membrane/SnO2/ITO/glass according to a preferred embodiment of the present invention;

FIGS. 2a and 2b are schematic views of structural formulas of berberine and silicotungstic acid hydrate respectively;

FIG. 3 is a schematic view of the relation between a voltage of an extended gate field effect transistor of a separate architecture and a pH value according to a preferred embodiment of the present invention;

FIG. 4 is a schematic view of the relation between a voltage of an enzyme detection field effect transistor and the concentration of berberine;

FIG. 5 is a schematic view of the relation between the voltage of a PVC membrane detection field effect transistor and the concentration of berberine according to a preferred embodiment of the invention;

FIG. 6 is a schematic view of the voltage response comparison between an enzyme and a PVC membrane detection field effect transistors in berberine with a concentration of 1×10−3M according to a preferred embodiment of the invention;

FIG. 7 is a schematic view of response balance time of an enzyme detection field effect transistor in berberine with a concentration of 1×10−3M according to a preferred embodiment of the invention;

FIG. 8 is a schematic view of the response balance time of a PVC membrane detection field effect transistor in berberine with a concentration of 1×10−3M according to a preferred embodiment of the invention;

FIG. 9 is a schematic view of the palmatine interfering a PVC membrane detection field effect transistor according to a preferred embodiment of the invention; and

FIG. 10 is a schematic view of a life cycle observation of a PVC membrane detection field effect transistor according to a preferred embodiment of the invention.

Table 1 is a comparison table of the sensitivity of the enzyme detection field effect transistor in different buffering liquids added with acetylcholinesterase of different concentrations;

Table 2 is a comparison table of the detection range and the sensitivity of a PVC membrane detection field effect transistor changing the composition proportion of the chemical membrane; and

Table 3 is a table of the properties of the PVC membrane detection field effect transistor;

Table 4 is a features comparison table of enzyme detection field effect transistor and PVC membrane detection field effect transistor.

### DETAILED DESCRIPTION OF THE PREFERRED EMBODIMENTS

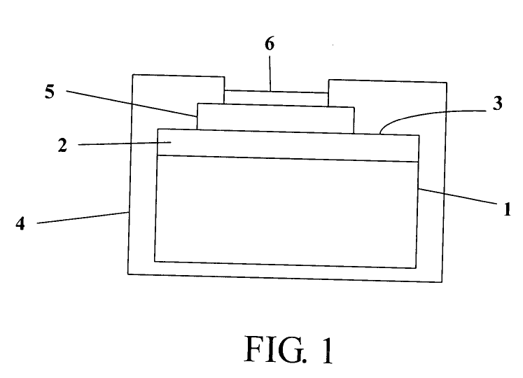

Referring to FIG. 1 for a cross-sectional view of an extended ion selective membrane/SnO₂/ITO/glass) with a separating architecture, the field effect transistor of an ionic architecture according to the present invention comprises a substrate 1; indium tin oxide (ITO) 2; a conductive wire 3; a sealing layer 4; and tin dioxide (SnO₂) 5.

The substrate 1 is preferably made of glass, which has the features of an easy availability and a low price. The indium tin oxide (ITO) 2 is formed on the glass substrate 1, and tin dioxide (SnO₂) is used to form an oxide layer on the indium tin oxide (ITO)2/glass 1 substrate, and a silver paste adjacent to the tin dioxide (SnO₂) layer 5 is used to fix a conductive wire 3 to the reserved portion of the indium tin oxide (ITO) 2. After the conductive wire 3 is fixed, a sealing layer 4 is used to package the components and just leave a sensing window 6, so as to complete the field effect transistor architecture of an extended ion architecture with a separating architecture according to the present invention.

The conductive wire 3 is preferably made of a metal including but not limited to aluminum, and the sealing layer 4 is made of a material including but not limited to an epoxy material, and the area of the sensing window is approximately 2×2 mm². The sensing principle of this field effect transistor is to put an ion detection electrode into a testing solution. Since the ion concentration of the testing solution varies, therefore the total number of ions of the interface electric dual layer varies accordingly, and the ions of the electric dual layer are dispersed by the electric attraction of the ion-selective substance to couple to the voltage detection electrode. Since the ion carries a positive or a negative charge, therefore when the testing ions get close to the voltage detection electrode, the electrode senses the voltage to produce potential signals. The chemical membrane 7 formed in the sensing window 6 can produce the extended ion-sensitive electrode (ISE) with a separating architecture, wherein the chemical membrane 7 includes but not limited to a berberine membrane 7 formed on the exposed oxide layer 5 of the sensing window 6 for detecting berberine.

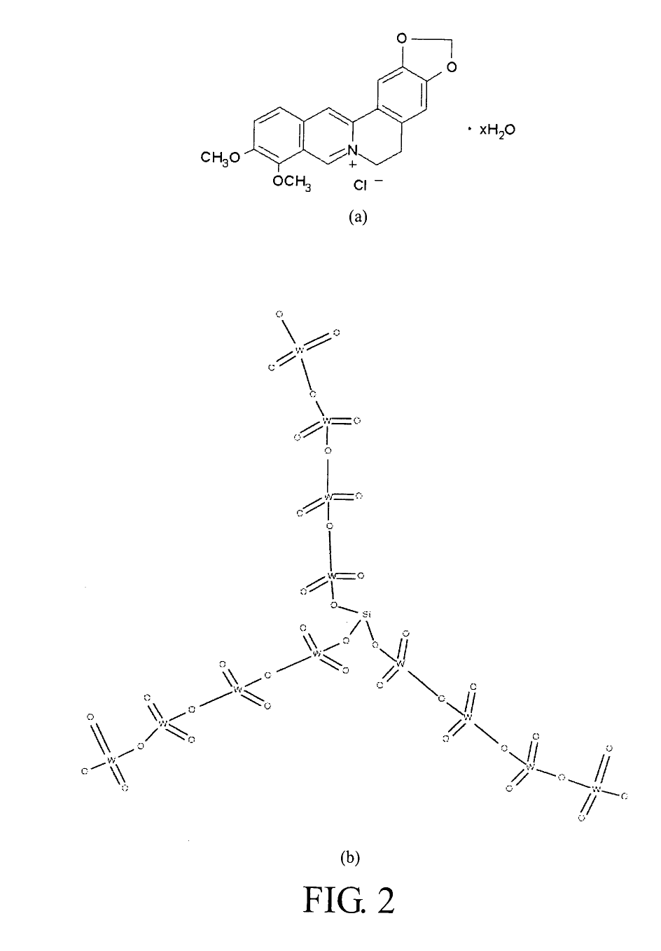

Referring to FIGS. 2a and 2b, the structural formula of berberine and silicotungstic acid hydrate are shown, and the silicotungstic acid hydrate is an electrocatalytic substance used for the PVC membrane detection field effect transistor. After the foregoing electrocatalytic substance is wrapped by PVC and placed into a highly concentrated berberine solution for activation, the testing solution can be measured and used as a solution for testing the berberine solution. Berberine is weak acid carrying electric charges. With the combination of the positive and negative ions, the property of a compound is formed. Scholars have successfully developed various ion-selective electrodes for testing the concentration of a specific ion, and the result is satisfactory. This study uses an electrocatalytic substance and a testing ion to form a compound having a “wide spectrum” property, and the produced ion field effect transistor has the selective, responsive, stable and recursive properties. The heteropolyacid hydrate such as silicotungstic acid hydrate ( STA) was found in 1979. This heteropolyacid hydrate shows an abnormal conductivity of macromolecules.

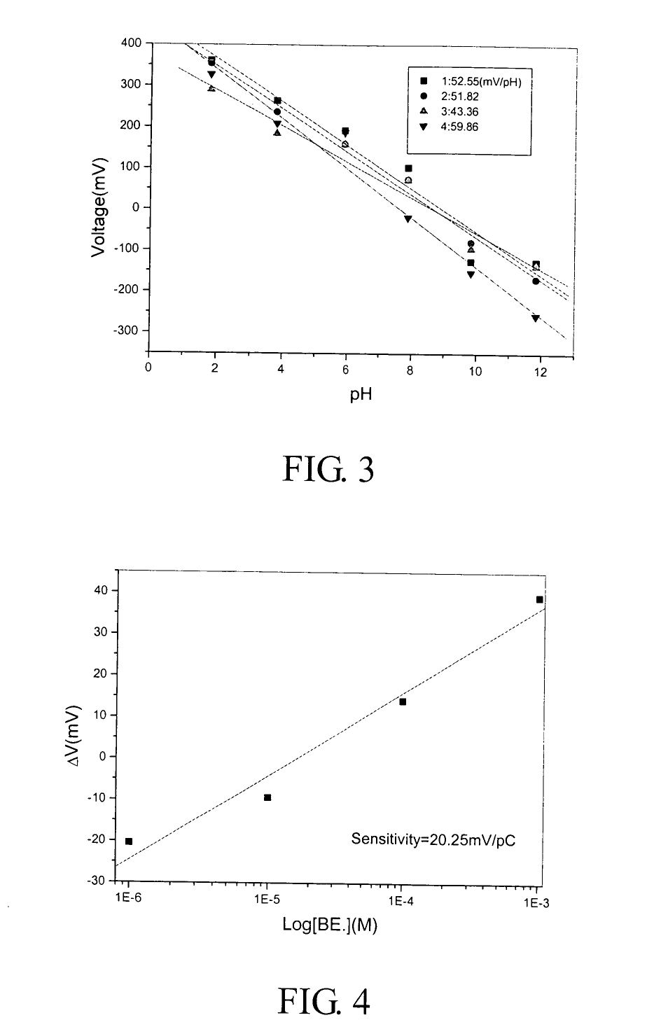

Referring to FIG. 3 for the schematic view of the sensitivity obtained from the response voltage by placing an extended detection field effect transistor with a separating architecture of the present invention into a solution with pH2˜12, the extended detection field effect transistor with a separating architecture is an acid/base sensor, which follows the balance between the concentration of hydrogen ion and surface bonding. If the membrane is placed in water solution, the surface of the membrane forms an adsorption for OH, O⁻, OH₂⁺. If there are lots of hydrogen ions in the solution, the O⁻ radical group and a portion of the water cations form an electric dual layer. From the description above, the ion sensitive field effect transistor has a membrane and solution surface that vary according to different concentrations of hydrogen ions to produce an interface potential change for detecting the concentration of the hydrogen ions.

Referring to FIG. 4 for the schematic view of the relation between the voltage of enzyme detection field effect transistor and the concentration of berberine according to the present invention, the enzyme detection field effect transistor has a buffering solution of 0.1 mM phosphate and a pH value of 7.4, and the buffering liquid has a sensitivity of 20.25 mV/pC, when no acetylcholinesterase is added. The reason of its low sensitivity may be caused by the enzyme of this sensor combined with the SnO₂ by covalent bonds, and the radicals of bonded enzyme may be the activation center of the catalysis that causes the enzyme to lose its radical catalytic mechanism, or may change its enzyme level to 3 or 4. The measuring method and use of the enzyme detection field effect transistor are shown in Table 1. If the buffering composition of the testing solution and the concentration of the competing substance are changed, the enzyme detection field effect transistor is affected by the change as shown in FIG. 4. If the composition of the buffering liquid includes phosphate and is free of a competing substance, a better sensitivity can be achieved. Further, if the proportion of the macromolecule, plastic member and electrocatalytic substance of the PVC membrane detection field effect transistor is changed as shown in Table 2, the detection range and sensitivity will be detected. If the proportion among the three (PVC/DOS/STA) is 33:66:33, the detection range will be wider and the sensitivity will be better.

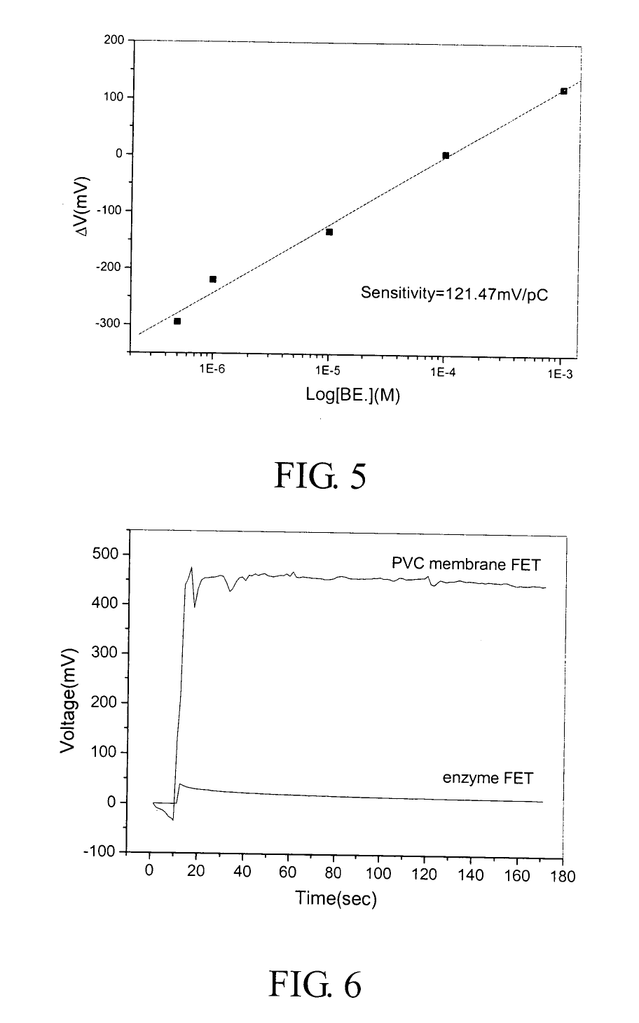

Referring to FIG. 5 for the schematic view of a relation between the voltage of a PVC membrane detection field effect transistor and the concentration of berberine in accordance with the present invention, the sensitivity of PVC membrane detection field effect transistor is 121.47 mV/pC, which has a much better sensitivity to berberine than the enzyme detection field effect transistor because berberine is a weak acid carrying electric charges. The electrocatalytic substance and testing ions form a compound having a “wide spectrum” property, and thus giving a very good detection property.

Referring to FIG. 6 for the schematic view of a comparison of the voltage response between the enzyme and PVC membrane detection field effect transistors in the berberine concentration of 1×10−3M in accordance with the present invention, the difference of the voltage response obtained by the enzyme and PVC membrane detection field effect transistors in the berberine concentration of 1×10−3M shows that the response voltage of the PVC membrane detection field effect transistor is 447.25 mV, and the response voltage of the enzyme detection field effect transistor is 20.49 mV. Therefore, the PVC membrane detection field effect transistor has a better response to berberine than the enzyme detection field effect transistor.

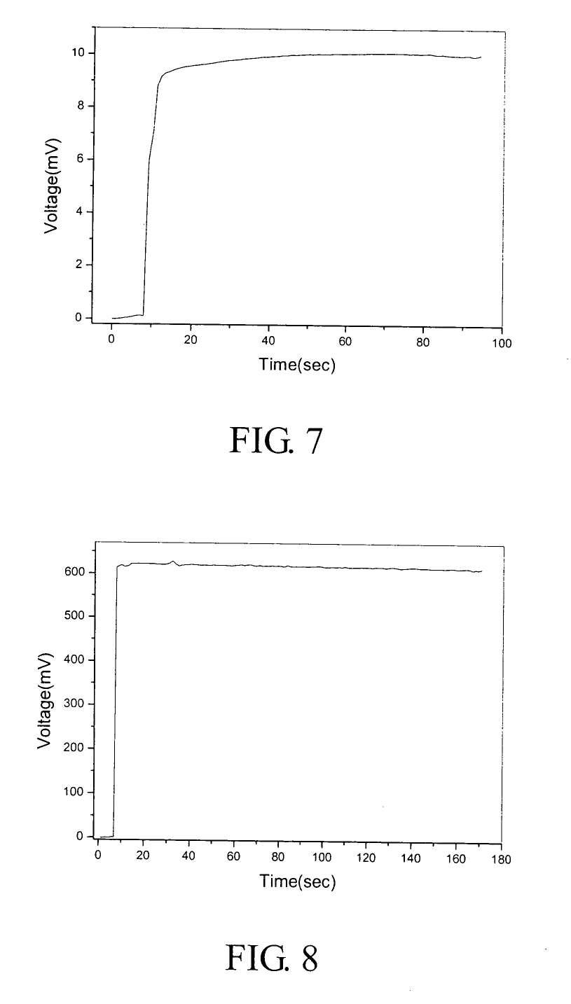

Referring to FIG. 7 for the schematic view of a response balance time of the enzyme detection field effect transistor in a berberine concentration of 1×10−3M in accordance with the present invention, the response time to berberine of the enzyme detection field effect transistor of the invention is longer and takes more than 60 seconds. A possible reason is that the structures of berberine and acetylcholinesterase are similar but are not composed of identical matters. Therefore, the reaction between berberine and enzyme takes longer time.

Referring to FIG. 8 for the schematic view of a response balance time of a PVC membrane detection field effect transistor in a berberine concentration of 1×10−3M in accordance with the present invention, the response of the PVC membrane detection field effect transistor to the medicine membrane and berberine is faster, and thus the response time is shorter and takes less than 30 seconds. If a PVC membrane containing the silicotungstic acid hydrate is reacted with a berberine solution, the electrocatalytic substance which is a silicotungstic acid hydrate starts the deionization in water to produce hydrogen ions (This forms silicotungstic acid hydrate anion ([SiW12O40]4) which is a Keggin structure), and the macromolecules fixed by metal ions are left. These metal ions gradually react with the alkaloid molecules to produce bonding, and thus the silicotungstic acid hydrate in the berberine chemical membrane 7 and the berberine in the solution are bonded gradually in a stable state and then to a balance state. By then, the surface of the membrane responses stably, and this state keeps on going. After the silicotungstic acid hydrate ions are located at the internal side of the macromolecular membrane and enter into the berberine bond in the membrane, the direction of combining molecules is orderly, which is the reason for producing an interface potential, and this mode is a relation occurred with the membrane when the components are activated.

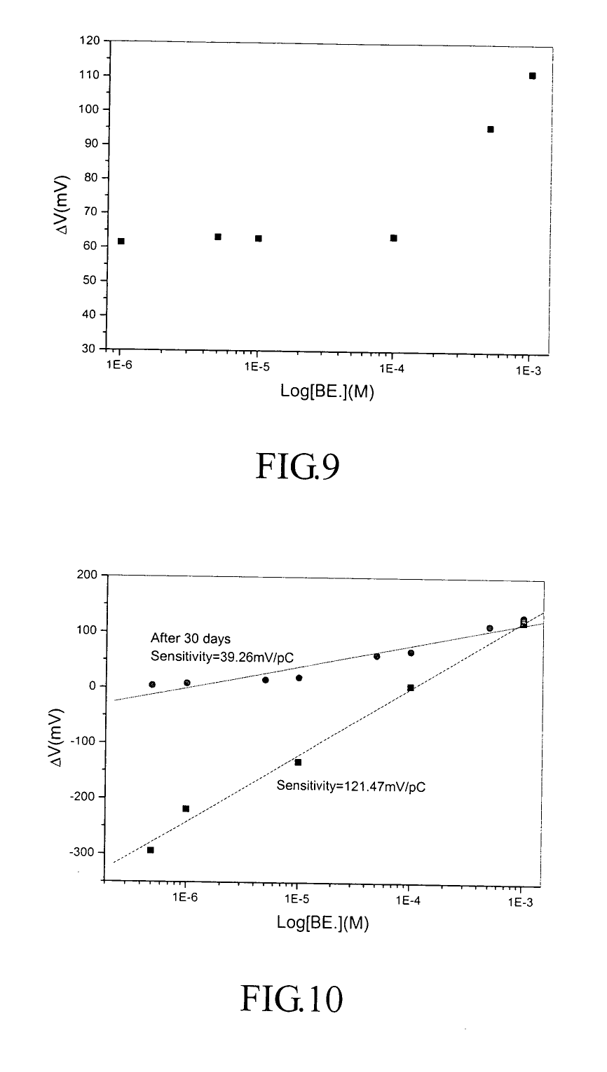

Referring to FIG. 9 for schematic view of the interference of palmatine to the PVC membrane detection field effect transistor of the present invention, it shows the relation between the PVC membrane detection field effect transistor and palmatine. Since many journals show that the structures and polarities of palmatine and berberine are very similar, and thus the palmatine in a berberine solution of different concentrations is added to a fixed quantity 5×10−4M. FIG. 9 shows that if the sensor detects a berberine with a low concentration, the signal of a response voltage has been saturated and indicates that the original berberine signal has been replaced by palmatine, and thus palmatine definitely will interfere with the berberine sensor of the PVC membrane detection field effect transistor to a certain extent.

Referring to FIG. 10 for the schematic view of the life cycle of a PVC membrane detection field effect transistor of the present invention, it shows that the sensitivity of a PVC membrane detection field effect transistor measured in 30 days later drops from 121.47 mV/pC to 39.26 mV/pC, and thus its life cycle is less than 30 days.

In addition, the present invention also provides a method of producing an ion-sensitive electrode comprising the steps of: (a) cutting an indium tin oxide (ITO) substrate 2 into a desired size, and using a supersonic vibrator (not shown in the figure) to rinse the indium tin oxide (ITO) glass substrate 2 by methanol first and then by deionized water for a predetermined time; (b) using a radio frequency sputtering (R. F. Sputtering) (not shown in the figure) to splutter the tin dioxide (SnO₂) membrane 5 onto the indium tin oxide (ITO) glass substrate 2; (c) using a silver paste to fix a conductive wire 3 onto a reserved portion of the indium tin oxide (ITO) glass substrate 2 after the membrane 5 is spluttered, and placing the substrate 2 into a high-temperature oven (not shown in the figure) for a predetermined time; (d) using a sealing layer 4 to package the components and leaving a window 6 in contact with the membrane 5 after the conductive wire 3 is fixed, and placing the substrate into the oven (not shown in the figure) for a predetermined time after the packaging is completed, and completing the production of the extended gate field effect transistor with a separating architecture after the sealing layer 4 is hardened.

In Step (a), the indium tin oxide (ITO) glass substrate 2 is rinsed by the methanol and deionized water each for 15 minutes. In Step (b), the tin dioxide (SnO₂) membrane 5 is spluttered with a thickness of approximately 2000 Å onto the indium tin oxide (ITO) glass substrate 2. In Step (c), the indium tin oxide (ITO) glass substrate 2 is placed in a high-temperature oven at 150° C. for approximately 40 minutes. In Step (d), the sealing layer 4 is made of an epoxy material, and the window has an area of approximately 2×2 mm².

The method of producing an ion-sensitive electrode in accordance with the present invention further comprises a step of vibrating the packaged detection electrode by a supersonic vibrator containing deionized water (D.I. water) for about 20 minutes, and further comprises a step of fixing a medicine membrane 7 onto the sensing window 6 of the electrode, wherein the medicine membrane 7 is a (PVC) membrane having the following composition: (al) polyvinyl chloride (PVC): 33%, Bis2-ethylhexyl sebacate (DOS): 66%, and silicotungstic acid hydrate (STA):33% are mixed according to a specific proportion and added with 0.4 ml of the solvent tetrahydroofuran (THF), and mixed by a supersonic vibrator. The mixing rate of the PVC is fast and will be evenly fixed within 5 minutes, and then 2.0 μl of the mixed solution is taken and dropped onto the sensing window. The medicine membrane 7 could be an enzyme sensor having the following composition: 2.0 μl of 3-glycidoxypropyltrimethoxy silane (GPTS) is dropped onto a sensing window 6 and dried in an oven at 100□ for an hour, and removed for cooling, and then 2.0 μl of acetylcholinesterase (AchE) is dropped onto the sensing window 6 fixed with GPTS and then dried at room temperature.

The present invention also provides a potential detection method using an ion-sensitive electrode that comprises the steps of: (a) using a meter amplifier (not shown in the figure) as a read-out circuit; (b) contacting the medicine membrane 7 of the berberine selective electrode with the buffering solution; and (c) using a voltage-time correction curve as the potential response curve.

The medicine membrane 7 is a PVC membrane or an enzyme membrane; wherein different macromolecules, plastic members and electrocatalytic substance of the PVC membrane detection field effect transistor affect the sensitivity, and their preferred proportion is 33:66:33, and the component life of the PVC membrane detection field effect transistor deteriorates according to the disposing time, and this component life cycle should be less than 30 days, wherein the optimal sensitivity of the PVC membrane detection field effect transistor is 121.47 mV/pC, and the optimal sensitivity of the enzyme detection field effect transistor is 20.25 mV/Pc. The response time of the enzyme membrane detection field effect transistor is longer than the response time of the PVC membrane detection field effect transistor, which are greater than 60 seconds and less than 30 seconds respectively. The detection range of the enzyme and PVC membrane detection field effect transistors are 1×10⁻³˜1×10⁻⁷M and 1×10⁻³˜×10⁻⁷M respectively.

The PVC membrane detection field effect transistor further comprises an interfering substance including but not limited to palmatine, wherein the condition of the buffering liquid of the enzyme membrane detection field effect transistor as described in Step (b) contains 0.1M phosphate. If the buffering liquid is added with a competing substance, the sensitivity of the enzyme membrane detection field effect transistor will drop, wherein the competing substance includes but not limited to acetylchol inesterase.

The extended gate field effect transistor with a separating architecture adopts two methods for detecting berberine: (1) forming a PVC membrane on a sensing window 6 to produce a PVC membrane detection field effect transistor with the composition as follows: mixing polyvinyl chloride (PVC), Bis2-ethylhexyl sebacate (DOS), and silicotungstic acid hydrate (STA), and the proportion of PVC and DOS is 33:66, and the proportion of the three (PVC/DOS/STA) is preferably 33:66:33. After the three constituents are mixed, 0.4 ml of etrahydroofuran (THF) solution is used for mixing by a supersonic vibrator. The speed of mixing the three constituents is fast, so that the constituents can be mixed evenly within 5 minutes, and then 2.01 μl of the mixed solution is dropped onto the sensing window; (2) forming the enzyme membrane onto the sensing window 6 to produce the enzyme membrane detection field effect transistor with the following composition: 2.0 μl of 3-glycidoxypropyltrimethoxy silane (GPTS) is dropped onto the sensing window and dried in an oven at 100□ for an hour, and then removed for cooling; 2.0 μl of acetylcholinesterase (AchE) is dropped onto a sensing window fixed with GPTS and dried at room temperature. After the reaction is completed, the two components are placed into 1×10−3M of berberine solution and 0.1M phosphate at pH of 7.4 and at room temperature for 24 hours for the activation to complete the process of fixing the berberine electrode. Finally, the measurement of the experiment is started. After the measurement is completed, the components of the macromolecular membrane are stored at room temperature, and the enzyme components are stored in a dark box at 4° C. for the next use.

In summation of the foregoing preferred embodiments, the advantages of the invention are listed below:

1. In the enzyme detection field effect transistor of the invention as shown in Table 1, it shows that the sensitivity of the enzyme detection field effect transistor varies according to the acetylcholinesterase of different concentration being added into the buffering liquid. From Table 1, it is found that the buffering liquid has 0.1mM phosphate and a pH value of 7.4. If acetylcholinesterase is not added, the enzyme detection field effect transistor has its optimal sensitivity, since both berberine and acetylcholinesterase have similar structural formula. If the buffering liquid has no acetylcholinesterase added, the competition of combining with the enzyme drops, and thus relatively improving the sensitivity,

2. In the PVC membrane detection field effect transistor as shown in Table 2, the sensitivity and detection range of the PVC membrane detection field effect transistor are observed when the proportion among the macromolecules, plastic member, and electrocatalytic substance of the medicine membrane 7 is changed. From Table 2, it is known that the plastic member is DOS, and the proportion among the macromolecules, plastic members, and electrocatalytic substance is 33:66:33, and the detection range is very wide and falls in the range of 1×10−3˜5×10−7M, and its sensitivity is very good and has a value of 121.47 mV/pC.

3. In the method of producing and measuring of the invention as shown in Table 3, the PVC membrane detection field effect transistor of the invention is compared with related references. Table 3 shows that the membrane used by the PVC membrane detection field effect transistor of the invention is SnO₂ and the plastic member is DOS. If the simulated reference adopts DOP as the plastic member, then the life cycle of the invention is not as good as the reference (which can be stored for over 6 months). Although the sensor of the invention has a better sensitivity than the reference, yet the detection range is narrower and the life cycle is shorter than the reference, provided the interfering substance is palmatine for both cases.

The berberine selective electrode has been disclosed in the foregoing preferred embodiments. Although the sensitivity, preparing process, and cost of the enzyme detection field effect transistor are not as good as those of the PVC membrane field effect transistor as shown in Table 4, the PVC membrane field effect transistor has better sensitivity, linearity and stability. Very little interference to the PVC membrane field effect transistor will be caused by many substances, and thus the present invention improves over the prior art and complies with the requirements of patent applications. The measuring property of the berberine electrode is a preferred embodiment, but the method is not limited to the detection of medicine compositions of Chinese herbs. The description and its accompanied drawings are used for describing preferred embodiments of the present invention, and it is to be understood that the invention is not limited thereto. To the contrary, it is intended to cover various modifications and similar arrangements and procedures, and the scope of the appended claims therefore should be accorded the broadest interpretation so as to encompass all such modifications and similar arrangements and procedures.

TABLE 1

| | Concentration of added | |
|---|---|---|
| Buffering Liquid | acetylcholinesterase (mM) | Sensitivity (mV/pC) |
| 0.1 mM Phosphate | 0 | 31.09 |
| | 10 | 14.14 |
| | 20 | 3.47 |
| | 30 | 1.54 |
| 1 mM Phosphate | 10 | 1.36 |
| | 20 | 3.48 |
| | 30 | 2.21 |
| 10 mM Phosphate | 10 | 5.82 |
| | 20 | 3.14 |
| | 30 | 2.03 |
| 0.1 mM Buffering | 10 | 8.807 |
| Phosphate | 20 | 10.06 |
| | 30 | 11.39 |
| 10 mM Buffering | 10 | 4.65 |
| Phosphate | 20 | 2.58 |
| | 30 | 1.31 |

TABLE 2

| Macromolecular | | | |
|---|---|---|---|
| Composition and | | | |
| Proportion | | Detection Range (M) | Sensitivity (mV/pC) |
| PVC:DOP:STA | 1.5:4:2.5 | 1 × 10⁻³˜5 × 10⁻⁶ | 67.1 |
| | 2:3.5:3 | 1 × 10⁻³˜5 × 10⁻⁵ | 96.73 |
| | 3.3:6.6:1 | 1 × 10⁻³˜5 × 10⁻⁶ | 69.28 |
| | 2.8:6.6:1 | 1 × 10⁻³˜1 × 10⁻⁵ | 43.22 |
| PVC:DOS:STA | 2:3.5:3 | 1 × 10⁻³˜5 × 10⁻⁵ | 121.14 |
| | 3.3:6.6:1 | 1 × 10⁻³˜7 × 10⁻⁵ | 52.44 |
| | 3.3:6.6:3.3 | 1 × 10⁻³˜5 × 10⁻⁵ | 121.47 |
| | 3.3:6.6:4.4 | 1 × 10⁻³˜5 × 10⁻⁶ | 54.15 |

TABLE 3

| | | Experiment | |
|---|---|---|---|
| Condition | | Parameter | Reference Parameter |
| Detection Membrane Material | | SnO₂ | Si₃N₄ |
| Sensitivity (mV/pC) | | 121.47 | 59.1 |
| Detection Range (M) | | 1 × 10⁻³˜5 × 10⁻⁷ | 1 × 10⁻³˜2 × 10⁻⁷ |
| Lift Time | | <30 days | 6 months |
| Detection | Plastic Member | DOS | DOP |
| Membrane | Proportion of | 33:66:33 | — |
| | Macromolecule, | | |
| | Plastic Member, | | |
| | and Activating | | |
| | Agent | | |
| Inter- | NaCl | 1.51 × 10⁻⁸ | 1.1 × 10⁻⁵ |
| ference | KCl | 2.04 × 10⁻² | 1.0 × 10⁻⁵ |
| Coef- | Urea | 3.47 × 10⁻³ | 1.0 × 10⁻⁴ |
| ficient | Glucose | 4.27 × 10⁻⁴ | 1.0 × 10⁻⁵ |
| | Ascorbate | Interfered | — |
| | Palmatine | Interfered | Interfered |

TABLE 4

| | | PVC Membrane |
|---|---|---|
| | Enzyme Detection Field | Detection |
| | Effect Transistor | Field Effect Transistor |
| Activating Matter | Acetylcholinesterase | Silicotungstic acid |
| Reference Electrode | Ag/AgCl | Ag/AgCl |
| Buffering Liquid | 0.1 mM Phosphate | Deionized Water |
| pH Value | 7.4 | — |
| Temperature | 25° C. | 25° C. |
| Storage Temperature | 4° C. | Room Temperature |
| Cost | High | Low |
| Reaction Time | >60 seconds | <30 seconds |
| Linear Range | 1 × 10⁻³˜1 × 10⁻⁷ M | 1 × 10⁻³˜1 × 10⁻⁶ M |
| Dectability | 20.25 mV/pC | 121.47 mV/pC |

What is claimed is:

1. An gate field effect transistor with a separating architecture, comprising:
an indium tin oxide (ITO) /glass, used for forming a substrate;
a tin dioxide (SnO₂), used for forming an oxide layer; and
a sealing layer, for sealing said substrate and said oxide layer and only leaving a sensing windows that is in contact with a berberine membrane;
wherein said oxide layer is sputtered to deposit said tin dioxide onto said indium tin oxide (ITO)/glass substrate to form an extended gate field effect transistor (EGFET) with a separating architecture.

2. The gate field effect transistor with a separating architecture of claim 1, further comprises a conductive wire and a berberine chemical membrane, and said conductive wire is coupled with said indium tin oxide (ITO)/glass substrate, and said berberine chemical membrane is formed on said oxide layer and exposed from said sensing window for detecting berberine.

3. The gate field effect transistor with a separating architecture of claim 1, wherein said sensing window has an area of approximately 2×2 mm² and said sealing layer is made of an epoxy material.

4. The gate field effect transistor with a separating architecture of claim 2, wherein said conductive wire is made of aluminum metal.

5. A method of producing an ion-sensitive electrode, comprising the steps of:
(a) cutting an indium tin oxide (ITO) substrate into a desired size, and using a supersonic vibrator to rinsing said indium tin oxide (ITO) glass substrate by methanol first and then by ionic water later for a predetermined time;
(b)using a radio frequency sputtering method for spluttering a tin dioxide (SnO₂) membrane onto said indium tin oxide (ITO) glass substrate;
(c) using a silver paste to fix a conductive wire at a reserved portion of said indium tin oxide (ITO) glass substrate and placing said indium tin oxide (ITO) glass substrate into a high-temperature oven for a predetermined time, after said tin dioxide (SnO₂) membrane onto said indium tin oxide (ITO) glass substrate;
(d) using a sealing layer to package said components and leaving a window for being in contact with said membrane after said conductive wire if fixed, and placing said substrate into an oven for a determined time after said components are packaged; and completing the production of said extended gate field effect transistor after said sealing layer is hardened.

6. The method of claim 5, wherein said indium tin oxide (ITO) glass substrate described in step (a) is rinsed by methanol for 15 minutes first and then rinsed by ionic water for 15 minutes, and the thickness of said tin dioxide (SnO₂) membrane being spluttered onto said indium tin oxide (ITO) glass substrate as described in step (b) is approximately 2000 Å.

7. The method of claim 5, wherein said indium tin oxide (ITO) glass substrate as described in step (c) is placed in a high-temperature oven at 150° C. for approximately 40 minutes, and said sealing layer as described in step (d) is made of an epoxy, and said window has an area of approximately 2×2 mm.

8. The method of claim 5, further comprising a step of vibrating said packaged sensing electrode by a supersonic vibrator containing deionized water for approximately 20 minutes.

9. The method of claim 5, further comprising a step of fixing a medicine membrane onto said sensing window of said electrode.

10. The method of claim 9, wherein said chemical membrane is made of a polyvinyl chloride membrane composed of:
(al) polyvinyl chloride (PVC): 33%, Bis2-ethylhexyl sebacate (DOS): 66%, and silicotungstic acid hydrate (Silicotungstic acid (STA):33% mixed with a predetermined proportion, and then 0.4 ml of a tetrahydroofuran (THF) solution is added and mixed by a supersonic vibrator, and said PVC is mixed quickly and evenly in approximately 5 minutes, and 2.0 μl of the mixed solution is dropped onto said sensing window.

11. The method of claim 9, wherein said chemical membrane is enzyme sensor composed of: dropping 2.0 μl of 3-glycidoxypropyltrimethoxy silane (GPTS) onto said sensing window and being dried in an oven at 100° C. for an hour, and removing said chemical membrane for cooling, and then dropping 2.0 μl of acetylcholinesterase (AchE) onto said sensing window fixed with GPTS, and being dried at room temperature.

12. A potential detection method using an ion-sensitive electrode, comprising the steps of:
(a1) using a meter amplifier as a read-out circuit;
(a2) contacting a chemical membrane of a berberine selective electrode with a buffering solution; and
(a3) using a voltage-time correction curve as a potential response curve.

13. The potential detection method of claim 12, wherein said chemical membrane is a PVC membrane or an enzyme membrane, and the optimal sensitivity of said enzyme field effect transistor is 20.25 mV/Pc, and the optimal sensitivity of said PVC membrane field effect transistor is 121.47 mV/pC.

14. The potential detection method of claim 13, wherein said PVC membrane sensitive field effect transistor comprises different macromolecules, plastic members and electrocatalytic substance affecting its sensitivity and preferably having a proportion of 33:66:33.

15. The potential detection method of claim 13, wherein said enzyme membrane detection field effect transistor has a longer response time than said PVC membrane detection field effect transistor, which are greater than 60 seconds and less than 30 seconds respectively.

16. The potential detection method of claim 13, wherein said PVC membrane detection field effect transistor further comprises an interfering substance such as palmatine.

17. The potential detection method of claim 13, wherein said enzyme membrane detection field effect transistor has a buffering liquid made of 0.1M phosphate.

18. The potential detection method of claim 13, wherein said enzyme membrane detection field effect transistor has a drop of sensitivity when a competing substance is added to said buffering liquid, and said competing substance is an acetylcholinesterase.

19. The potential detection method of claim 13, wherein said enzyme and PVC membrane field effect transistors have detection ranges of 1×10⁻³˜1×10⁻⁷M and 1×10⁻³˜×10⁻⁷M respectively.

20. The potential detection method of claim 13, wherein said PVC membrane detection field effect transistor has a component life deteriorating as its disposing time, and said component life is less than 30 days.
